(19) United States
(12) Patent Application Publication
(10) Pub. No.: US 2024/0006240 A1
(43) Pub. Date: Jan. 4, 2024

(54) DEVICE WAFER PROCESSING METHOD AND PROCESSING APPARATUS

(71) Applicant: DISCO CORPORATION, Tokyo (JP)

(72) Inventor: Naoko YAMAMOTO, Tokyo (JP)

(21) Appl. No.: 18/342,031

(22) Filed: Jun. 27, 2023

(30) Foreign Application Priority Data
Jul. 1, 2022 (JP) 2022-107241

(51) Int. Cl. H01L 21/78; H01L 21/304; H01L 21/268; H01L 21/683; H01L 21/02; H01L 21/67

(52) U.S. Cl. CPC H01L 21/78; H01L 21/3043; H01L 21/268; H01L 21/6836; H01L 21/02076; H01L 21/67092

(57) ABSTRACT

A device wafer processing method includes a holding step of holding a face side of a device wafer by a holding table, a cutting step of cutting the device wafer by a cutting blade from a reverse side of the device wafer along streets and forming cutting grooves that do not reach a functional layer, and a laser processing step of applying a laser beam having a wavelength absorbable by the device wafer to the device wafer from the reverse side of the device wafer along the cutting grooves and dividing the device wafer into individual devices. The laser processing step is carried out in a state in which the device wafer is continuously held on the holding table without being unloaded from the holding table, after the cutting step is carried out.

### BACKGROUND OF THE INVENTION

### Field of the Invention

The present invention relates to a device wafer processing method and a processing apparatus.

### Description of the Related Art

In recent years, in association with higher integration of devices, hybrid bonding, which is a method of connecting electrodes formed on face sides of device wafers to each other, has come into use. In hybrid bonding, since the face sides of the device wafers are bonded to each other, adherence of foreign matter to the face side of the wafer could cause bonding failures. Hence, in hybrid bonding, there is a demand for reduced adherence of foreign matter to the face side of the diced device wafer, compared to conventional bonding performed with bumps.

Foreign matter that adheres to the diced device wafer is dicing swarf generated mainly by dicing of device wafers and tapes, and swarf that has been left unremoved in the subsequent cleaning step causes a problem at the time of bonding. Hence, affixing a tape to the face side of the device wafer and processing the device wafer from the reverse side are expected to reduce adherence of foreign matter to the face side of the device wafer.

However, there are limits on the depths of laser processing grooves that can be formed in a wafer, and dividing the wafer into individual devices by subjecting the wafer to full cutting requires a laser beam to be applied to the same street a number of times, resulting in poor productivity in some cases. Moreover, cutting a wafer by a cutting blade and dividing it into individual devices cause the problem of large chipping and cracking on the face side of the wafer supported by a tape.

One possible method is to form cutting grooves by subjecting the device wafer to half cutting from a reverse side thereof with use of a cutting blade, apply a laser beam along the cutting grooves, and then divide the face side of the wafer (see, for example, Japanese Patent Laid-open No. 2014-165246).

### SUMMARY OF THE INVENTION

In the past, a device wafer has first been processed by a cutting apparatus including a cutting blade, and has then been delivered from the cutting apparatus to a laser processing apparatus to be subjected to laser processing. However, this processing involves the risk of breakage of the device wafer at the time of attaching or detaching the device wafer formed with the cutting grooves to or from a holding table of the cutting apparatus or the laser processing apparatus or delivering the device wafer from the cutting apparatus to the laser processing apparatus.

It is accordingly an object of the present invention to provide a processing method and a processing apparatus that reduce adherence of foreign matter to a face side of a device wafer and also reduce the risk of breakage of the device wafer.

In accordance with an aspect of the present invention, there is provided a device wafer processing method of dividing a device wafer having a plurality of devices formed on a face side thereof by a functional layer laminated on a substrate, along a plurality of intersecting streets that demarcate the devices, the processing method including a holding step of holding the face side of the device wafer by a holding table, a cutting step of cutting the device wafer by a cutting blade from a reverse side of the device wafer along the streets and forming cutting grooves that do not reach the functional layer, after the holding step is carried out, and a laser processing step of applying a laser beam having a wavelength absorbable by the device wafer to the device wafer from the reverse side of the device wafer along the cutting grooves and dividing the device wafer into individual devices, after the cutting step is carried out. The laser processing step is carried out in a state in which the device wafer is continuously held on the holding table without being unloaded from the holding table, after the cutting step is carried out.

Preferably, in the laser processing step, a liquid layer is formed on the reverse side of the device wafer, and the laser beam is applied to the device wafer through the liquid layer.

Preferably, the device wafer processing method further includes a water-soluble resin coating step of coating the face side of the device wafer with water-soluble resin before the holding step is carried out, and a tape affixing step of affixing a tape to the face side of the device wafer after the water-soluble resin coating step is carried out, and, in the holding step, the face side of the device wafer is held via the tape.

Preferably, the device wafer processing method further includes a reverse side cleaning step of cleaning the reverse side of the device wafer after the laser processing step is carried out, a transferring step of affixing a reverse side tape to the reverse side of the device wafer and removing the tape from the face side of the device wafer, after the reverse side cleaning step is carried out, and a face side cleaning step of cleaning the face side of the device wafer and removing the water-soluble resin, after the transferring step is carried out.

In accordance with another aspect of the present invention, there is provided a processing apparatus that divides a device wafer having a plurality of devices formed on a face side thereof by a functional layer laminated on a substrate, along a plurality of intersecting streets that demarcate the devices, the processing apparatus including a holding table that holds the face side of the device wafer, a cutting unit that has a spindle to which a cutting blade that cuts the device wafer held on the holding table is mounted, and a laser processing unit that includes a laser oscillator that emits a laser beam having a wavelength absorbable by the device wafer and a beam condenser that focuses the laser beam emitted from the laser oscillator, to the device wafer held on the holding table.

Preferably, the cutting unit includes a cutting liquid nozzle that supplies cutting liquid to the cutting blade, the laser processing unit further includes a liquid layer forming unit that supplies liquid to the reverse side of the device wafer held on the holding table and forms a liquid layer, and the laser processing unit applies the laser beam to the device wafer through the liquid layer.

The present invention produces such an advantageous effect of reducing adherence of foreign matter to the face side of the device wafer and also reducing the risk of breakage of the device wafer.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating an example of a configuration of a processing apparatus according to a first embodiment of the present invention;

FIG. 2 is a perspective view schematically illustrating a device wafer that is to be processed by the processing apparatus illustrated in FIG. 1;

FIG. 3 is a cross sectional view of main parts of the device wafer illustrated in FIG. 2;

FIG. 4 is a view schematically illustrating a configuration of a laser beam application unit of a laser processing unit included in the processing apparatus illustrated in FIG. 1;

FIG. 5 is a flowchart illustrating a flow of the processing method according to the first embodiment;

FIG. 6 is a perspective view schematically illustrating the device wafer that has undergone a tape affixing step of the processing method illustrated in FIG. 5;

FIG. 7 is a schematic cross-sectional side view illustrating a holding step of the processing method illustrated in FIG. 5;

FIG. 8 is a schematic cross-sectional side view illustrating a cutting step of the processing method illustrated in FIG. 5;

FIG. 9 is a cross sectional view of the main parts of the device wafer that has undergone the cutting step of the processing method illustrated in FIG. 5;

FIG. 10 is a schematic cross-sectional side view illustrating a laser processing step of the processing method illustrated in FIG. 5;

FIG. 11 is a cross sectional view schematically illustrating main parts of a beam condenser and a liquid ejector illustrated in FIG. 1;

FIG. 12 is a cross sectional view of the main parts of the device wafer that has undergone the laser processing step of the processing method illustrated in FIG. 5;

FIG. 13 is a flowchart illustrating a flow of the processing method according to a second embodiment of the present invention;

FIG. 14 is a schematic cross-sectional side view illustrating a water-soluble resin coating step of the processing method illustrated in FIG. 13;

FIG. 15 is a cross sectional view of the main parts of the device wafer that has undergone the water-soluble resin coating step of the processing method illustrated in FIG. 13;

FIG. 16 is a perspective view schematically illustrating the device wafer that has undergone the tape affixing step of the processing method illustrated in FIG. 13;

FIG. 17 is a schematic cross-sectional side view illustrating a reverse side cleaning step of the processing method illustrated in FIG. 13;

FIG. 18 is a perspective view schematically illustrating the device wafer that has undergone a transferring step of the processing method illustrated in FIG. 13;

FIG. 19 is a cross sectional view of the main parts of the device wafer that has undergone the transferring step of the processing method illustrated in FIG. 13; and

FIG. 20 is a schematic cross-sectional side view illustrating a face side cleaning step of the processing method illustrated in FIG. 13.

### DETAILED DESCRIPTION OF THE PREFERRED EMBODIMENTS

Embodiments of the present invention will be described in detail below with reference to the attached drawings. The present invention is not limited by the contents described in the following embodiments. Moreover, the components described below include those that can easily be assumed by a person skilled in the art and those that are substantially the same. Further, the configurations described below can be combined as appropriate. Furthermore, various omissions, replacements, or modifications can be made within the scope not departing from the gist of the present invention.

### First Embodiment

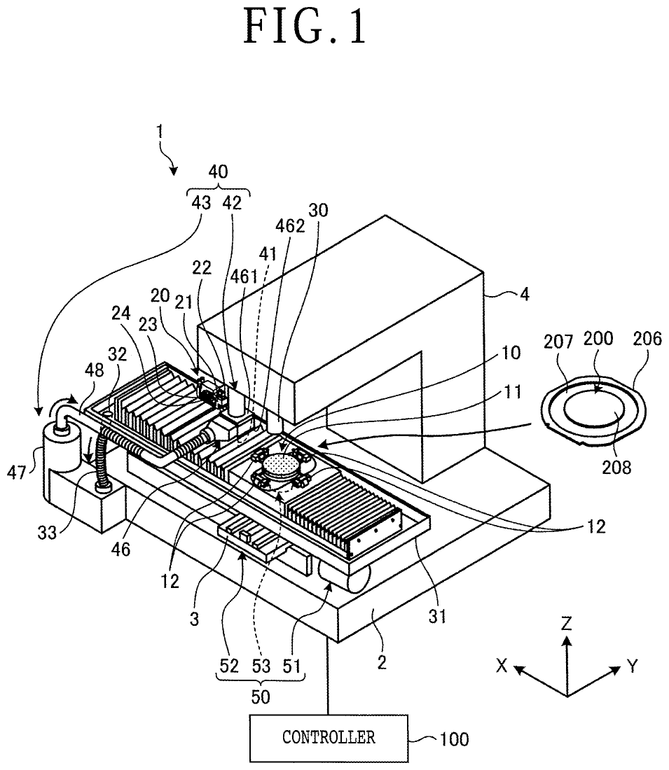

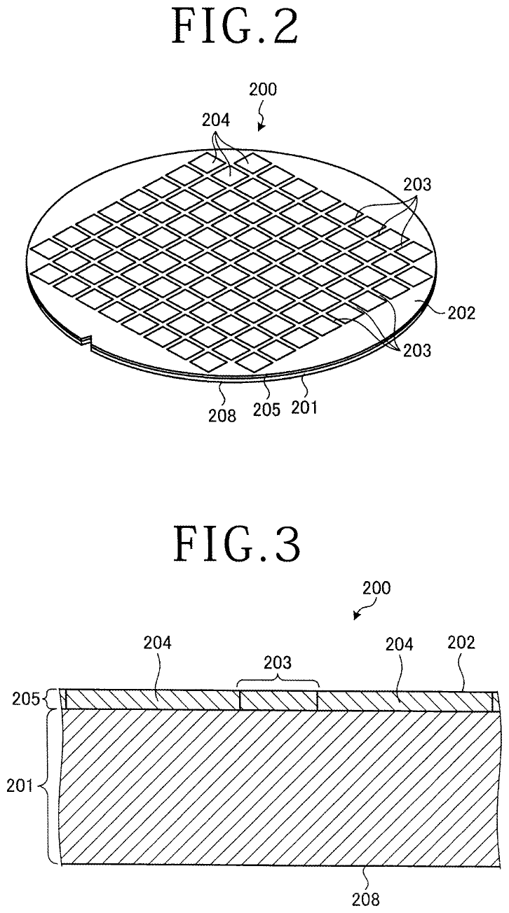

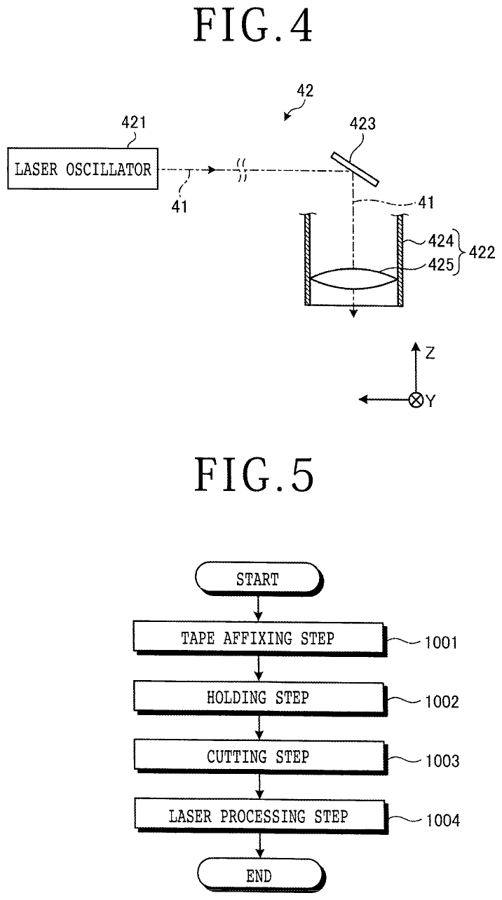

A processing apparatus according to a first embodiment of the present invention will be described in reference to the drawings. FIG. 1 is a perspective view illustrating an example of a configuration of the processing apparatus according to the first embodiment. FIG. 2 is a perspective view schematically illustrating a device wafer that is to be processed by the processing apparatus illustrated in FIG. 1. FIG. 3 is a cross sectional view of main parts of the device wafer illustrated in FIG. 2. FIG. 4 is a view schematically illustrating a configuration of a laser beam application unit of a laser processing unit included in the processing apparatus illustrated in FIG. 1.

The processing apparatus according to the first embodiment that is illustrated in FIG. 1 and denoted by 1 is an apparatus used for processing the device wafer illustrated in FIG. 2 and denoted by 200. In the first embodiment, the device wafer 200 is such a wafer as a circular plate-shaped semiconductor wafer that has a substrate 201 composed of silicon, sapphire, gallium arsenide, or silicon carbide (SiC). As illustrated in FIG. 2, the device wafer 200 has a plurality of devices 204 formed in respective areas demarcated in a grid pattern by a plurality of streets 203 on a face side 202 thereof.

The device 204 is, for example, an integrated circuit device such as an integrated circuit (IC) or a large scale integration (LSI) circuit, a charge coupled device (CCD), or a memory (semiconductor storage device). Further, the device 204 has unillustrated electrodes formed on its face side. Each of the electrodes is flat, and, in the first embodiment, is preferably positioned to be flush with the face side of the device 204. The electrode includes conductive metal such as copper alloy and is used to connect the device 204 of the device wafer 200 with a device of another wafer or a device of a device chip.

Specifically, in the first embodiment, the device wafer 200 is a wafer in which a device of another wafer or a device of a device chip is superposed on the device 204 and the electrodes of the device 204 are bonded to the electrodes of the device of the other wafer or the device of the relevant device chip. As described above, in the first embodiment, the device wafer 200 to be processed by the processing apparatus 1 is a wafer that is obtained by what is generally called hybrid bonding. However, the wafer to which the present invention is applicable is not limited to a wafer that is obtained by hybrid bonding.

In the first embodiment, as illustrated in FIGS. 2 and 3, the device wafer 200 includes a functional layer 205 that is an organic film on the substrate 201. The functional layer 205 includes a low dielectric constant insulation film (hereinafter referred to as a low-k film) including an inorganic film such as SiOF or BSG (SiOB), an organic film such as a polyimide-based or parylene-based polymer film, or a carbon-doped silicon oxide (SiOCH) film and a circuit layer including conductive metal patterns or metal films.

The low-k film is an interlayer insulating film and is laminated with the circuit layer to form the device 204. The circuit layer configures the circuit of the device 204. Thus, the device 204 includes the low-k films laminated one on top of another in the functional layer 205 laminated on the substrate 201 and the circuit layer disposed between the low-k films. In the streets 203, the functional layer 205 is composed of the low-k films laminated on the substrate 201, except the test elementary group (TEG).

In the first embodiment, the device wafer 200 includes unillustrated TEGs in the streets 203. TEGs are evaluation elements for finding design or manufacturing problems that occur in the devices 204. The functional layer 205 as exemplified by low-k films and TEGs are easily peeled off from the substrate 201 when the device wafer 200 is cut by a cutting blade from the face side 202. As described above, in the first embodiment, the device wafer 200 has the devices 204 formed on the face side 202 by the functional layer 205 laminated on the substrate 201.

In the first embodiment, a tape 207 which has an outer peripheral edge to which an annular frame 206 is mounted is affixed to the face side 202, and the device wafer 200 is supported by the annular frame 206. Note that, in the first embodiment, the tape 207 is what is generally called an adhesive tape including a glue layer including adhesive resin and a base material that includes non-adhesive resin and on which the glue layer is laminated. Yet, in the present invention, the tape 207 may be what is generally called a non-adhesive tape including only a base material including non-adhesive thermoplastic resin such as polyolefin or polyethylene. In a case where the tape 207 is a non-adhesive tape, the tape 207 is affixed to the device wafer 200 and the annular frame 206 by thermocompression bonding.

The processing apparatus 1 illustrated in FIG. 1 is an apparatus that holds the device wafer 200 by a holding table 10 and divides the device wafer 200 along the streets 203 that demarcate the devices 204. As illustrated in FIG. 1, the processing apparatus 1 includes the holding table 10 that holds under suction the face side 202 of the device wafer 200 by a holding surface 11, a cutting unit 20 that is a processing unit for performing cutting processing on the device wafer 200 held by the holding table 10 by a cutting blade 21, an imaging unit 30 that captures an image of the device wafer 200 held by the holding table 10, a laser processing unit 40, and a controller 100.

Further, as illustrated in FIG. 1, the processing apparatus 1 includes a moving unit 50 that moves the holding table 10 and the cutting unit 20 relative to each other. The moving unit 50 includes an X-axis moving unit 51 that processing feeds the holding table 10 in an X-axis direction parallel to a horizontal direction, a Y-axis moving unit 52 that indexing feeds the cutting unit 20 in a Y-axis direction parallel to the horizontal direction and orthogonal to the X-axis direction, an unillustrated Z-axis moving unit that incising feeds the cutting unit 20 in a Z-axis direction orthogonal to both the X-axis direction and the Y-axis direction and parallel to a vertical direction, and a rotational moving unit 53 that rotates the holding table 10 about its axis parallel to the Z-axis direction.

The X-axis moving unit 51 is disposed on an apparatus body 2. The X-axis moving unit 51 moves a moving table 3 in the X-axis direction that is a processing feed direction to move the holding table 10 in the X-axis direction and thereby processing feed the holding table 10, the cutting unit 20, and the laser processing unit 40 relative to one another along the X-axis direction. The Y-axis moving unit 52 is disposed on the moving table 3. The Y-axis moving unit 52 moves the holding table 10 and the rotational moving unit 53 in the Y-axis direction that is an indexing feed direction to thereby indexing feed the holding table 10, the cutting unit 20, and the laser processing unit 40 relative to one another along the Y-axis direction. The Z-axis moving unit is disposed on an upstanding column 4 erected from the apparatus body 2. The Z-axis moving unit moves the cutting unit 20 in the Z-axis direction that is an incising feed direction to thereby incising feed the holding table 10 and the cutting unit 20 relative to each other along the Z-axis direction.

The X-axis moving unit 51 includes a known ball screw provided in such a manner as to be rotatable about its axis, a known motor that rotates the ball screw about its axis and moves the holding table 10 in the X-axis direction, and known guide rails that support the holding table 10 in a movable manner in the X-axis direction. Similarly, the Y-axis moving unit 52 includes a known ball screw provided in such a manner as to be rotatable about its axis, a known motor that rotates the ball screw about its axis and moves the cutting unit 20 in the Y-axis direction, and known guide rails that support the cutting unit 20 in a movable manner in the Y-axis direction. The Z-axis moving unit also includes a known ball screw provided in such a manner as to be rotatable about its axis, a known motor that rotates the ball screw about its axis and moves the cutting unit 20 in the Z-axis direction, and known guide rails that support the cutting unit 20 in a movable manner in the Z-axis direction. The rotational moving unit 53 includes a known motor that rotates the holding table 10 about its axis, for example.

The holding table 10 has a disc shape, and the holding surface 11 that holds the device wafer 200 is formed of porous ceramics or the like. The holding table 10 is provided to be movable by the X-axis moving unit 51 in the X-axis direction between a processing area that is on a lower side of the cutting unit 20 and a loading/unloading area that is distanced from the processing area on the lower side of the cutting unit 20 and that is a place where the device wafer 200 is loaded or unloaded. The holding table 10 is also provided to be movable in the Y-axis direction together with the rotational moving unit 53, by the Y-axis moving unit 52. The holding table 10 is further provided to be rotatable about its axis parallel to the Z-axis direction by the rotational moving unit 53.

The holding table 10 is connected to an unillustrated vacuum suction source. When the holding table 10 is sucked by the vacuum suction source, the device wafer 200 placed on the holding surface 11 is sucked and held by the holding table 10. In the first embodiment, the holding table 10 sucks and holds the face side 202 of the device wafer 200 via the tape 207. Moreover, around the holding table 10, there are provided a plurality of clamps 12 that clamp the annular frame 206.

The cutting unit 20 is cutting means on which the cutting blade 21 that cuts the device wafer 200 held on the holding table 10 is mounted in an attachable/detachable manner. The cutting unit 20 can position the cutting blade 21 at any position on the holding surface 11 of the holding table 10 by the X-axis moving unit 51, the Y-axis moving unit 52, and the Z-axis moving unit.

As illustrated in FIG. 1, the cutting unit 20 includes the cutting blade 21, a spindle housing 22 provided to be movable in the Z-axis direction by the Z-axis moving unit, a spindle 23 that is provided, as a rotational axis, in the spindle housing 22 to be rotatable about its axis, an unillustrated spindle motor that rotates the spindle 23 about its axis, and a cutting liquid nozzle 24 that supplies cutting liquid to the cutting blade 21.

The cutting blade 21 is an extremely thin cutting grindstone that has a substantially ring shape and cuts the device wafer 200 held on the holding table 10. In the first embodiment, the cutting blade 21 includes an annular cutting edge that cuts the device wafer 200 and an annular base that supports the cutting edge on its outer edge and that is mounted to the spindle 23 in an attachable/detachable manner. The cutting edge includes abrasive grains of diamond or cubic boron nitride (CBN), for example, and a bonding member (binder) made of metal or resin, for example, and is formed to have a predetermined thickness. Both surfaces of the cutting edge are parallel to the X-axis direction. Note that, in the present invention, the cutting blade 21 may be what is generally called a washer blade that includes only a cutting edge.

The spindle housing 22 is supported in a movable manner in the Z-axis direction by the Z-axis moving unit. The spindle housing 22 houses portions of the spindle 23 except the distal end portion thereof and an unillustrated spindle motor, for example, and supports the spindle 23 in a rotatable manner about its axis.

The spindle 23 has the distal end portion on which the cutting blade 21 is mounted. The spindle 23 is rotated by the unillustrated spindle motor and has the distal end portion protruding from a distal end surface of the spindle housing 22. The distal end portion of the spindle 23 is formed to be tapered toward the distal end and has the cutting blade 21 mounted thereon. The spindle 23 of the cutting unit 20 and the axis of the cutting blade 21 are parallel to the Y-axis direction.

The imaging unit 30 is fixed to a distal end portion of the upstanding column 4, and is disposed to be lined with the cutting unit 20 in the X-axis direction. The imaging unit 30 includes an imaging element that captures an image of a to-be-divided area of the unprocessed device wafer 200 held on the holding table 10. The imaging element is, for example, a CCD imaging element or a complementary metal oxide semiconductor (CMOS) imaging element. The imaging unit 30 captures an image of the device wafer 200 held on the holding table 10, obtains an image to be used for performing, for example, alignment for aligning the device wafer 200 and the cutting blade 21, and outputs the obtained image to the controller 100.

Further, the processing apparatus 1 includes an unillustrated X-axis direction position detecting unit for detecting the position of the holding table 10 in the X-axis direction, an unillustrated Y-axis direction position detecting unit for detecting the position of the holding table 10 in the Y-axis direction, and a Z-axis direction position detecting unit for detecting the position of the cutting unit 20 in the Z-axis direction. The X-axis direction position detecting unit may include a linear scale parallel to the X-axis direction and a reading head. Similarly, the Y-axis direction position detecting unit may include a linear scale parallel to the Y-axis direction and a reading head. The Z-axis direction position detecting unit detects the position of the cutting unit 20 in the Z-axis direction by a pulse of the motor. The X-axis direction position detecting unit outputs the position of the holding table 10 in the X-axis direction to the controller 100. Similarly, the Y-axis direction position detecting unit outputs the position of the holding table 10 in the Y-axis direction to the controller 100, and the Z-axis direction position detecting unit outputs the position of the cutting unit in the Z-axis direction to the controller 100. Note that, in the first embodiment, the positions of the components of the processing apparatus 1 in the X-axis direction, the Y-axis direction, and the Z-axis direction are defined in reference to an unillustrated predetermined reference position.

The laser processing unit 40 applies a laser beam 41 having a wavelength absorbable by the device wafer 200 (i.e., both the substrate 201 and the functional layer 205) held on the holding table 10 and thereby performs what is generally called ablation processing on the device wafer 200. The laser processing unit 40 includes a laser beam application unit 42 and a liquid layer forming unit 43.

The laser beam application unit 42 is fixed to the distal end portion of the upstanding column 4 and is disposed to be lined with the cutting unit 20 and the imaging unit 30 in the X-axis direction. In the first embodiment, the laser beam application unit 42 is disposed between the cutting unit 20 and the imaging unit 30. The laser beam application unit 42 applies the laser beam 41 having a wavelength absorbable by the device wafer 200 held on the holding table 10.

As illustrated in FIG. 4, the laser beam application unit 42 includes a laser oscillator 421 that emits the laser beam 41, a beam condenser 422 that focuses the laser beam 41 emitted from the laser oscillator 421, to the device wafer 200 held on the holding table 10, and a mirror 423 that reflects the laser beam 41 emitted from the laser oscillator 421, toward the beam condenser 422.

The beam condenser 422 includes a tubular beam condenser body 424 and a focusing lens (fθ lens) 425 that is provided inside the beam condenser body 424, focuses the laser beam 41, and applies the laser beam 41 to the device wafer 200. The focusing lens 425 focuses the laser beam 41 reflected by the mirror 423 and applies the laser beam 41 to the device wafer 200 held on the holding table 10.

Further, the laser beam application unit 42 includes unillustrated focal point position adjustment means. The focal point position adjustment means moves the beam condenser 422 in the Z-axis direction and moves the focal point of the laser beam 41 in the Z-axis direction. The laser beam application unit 42 includes, for example, a ball screw that has a nut fixed to the beam condenser 422 and extends in the Z-axis direction and a motor that is coupled to one end portion of the ball screw and rotates the ball screw about its axis.

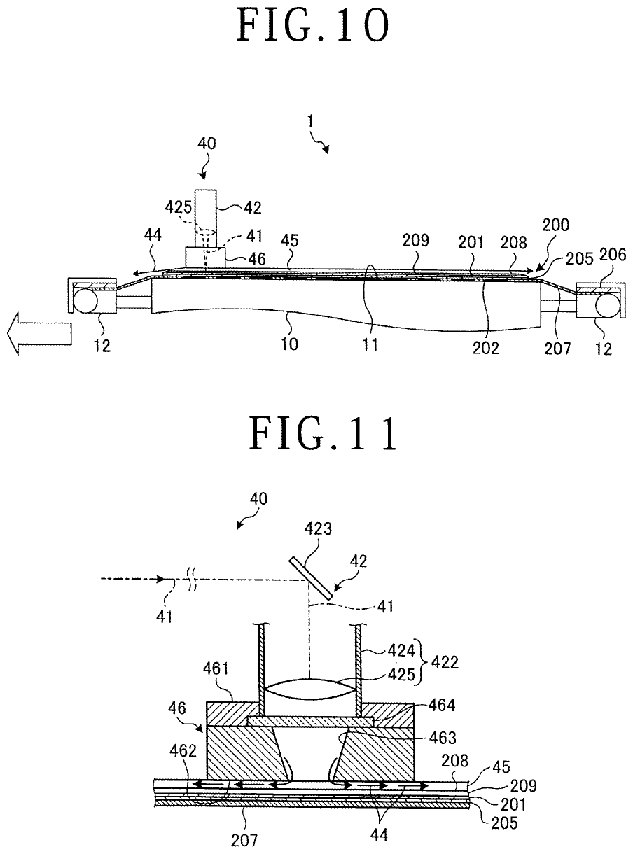

The liquid layer forming unit 43 supplies the liquid 44 (illustrated in FIGS. 10 and 11) to a reverse side 208 that is on a side opposite to the face side 202 of the device wafer 200 held on the holding table 10 and forms a liquid layer 45 (illustrated in FIGS. 10 and 11). Note that the liquid layer 45 is a layer that includes the liquid 44 and that is formed on the reverse side 208 of the device wafer 200. The liquid layer forming unit 43 includes, as illustrated in FIG. 1, a liquid ejector 46 that is attached to a lower end portion of the beam condenser 422, a liquid supply pump 47, and a pipe 48 that connects the liquid ejector 46 and the liquid supply pump 47.

As illustrated in FIG. 11, the liquid ejector 46 has formed therein a space 463 that is open in both an upper surface 461 and a lower surface 462 that are flat along the horizontal direction. The space 463 allows the laser beam 41 focused by the beam condenser 422 to pass therethrough. The liquid supply pump 47 supplies the liquid 44 to the space 463 inside the liquid ejector 46 through the pipe 48. The pipe 48 is in part or in whole configured from a flexible hose. An upper surface side of the space 463 is covered by a transparent plate 464 that has such a transparency that allows passage of the laser beam 41 applied from the beam condenser 422.

When the liquid 44 is supplied to the space 463 inside the liquid ejector 46 and the liquid 44 supplied to the space 463 flows on the reverse side 208 of the device wafer 200 from an opening on the lower surface 462 side, the liquid 44 forms the liquid layer 45 between the lower surface 462 of the liquid ejector 46 and the reverse side 208 of the device wafer 200 by the liquid layer forming unit 43.

As illustrated in FIG. 1, the processing apparatus 1 further includes a liquid collecting pool 31. The liquid collecting pool 31 is formed in a frame shape surrounding the rotational moving unit 53 that moves in the X-axis direction. The liquid collecting pool 31 collects cutting liquid and the liquid 44 and discharges them to the outside from a discharge port 32. In the first embodiment, a pipe 33 connected to the liquid supply pump 47 is connected to the discharge port 32. The pipe 33 is in part or in whole configured from a flexible hose.

The controller 100 controls various components of the processing apparatus 1 and causes the processing apparatus 1 to perform processing operations for the device wafer 200. Note that the controller 100 is a computer that includes an arithmetic processing device including a microprocessor as typified by a central processing unit (CPU), a storage device including a memory as typified by a read only memory (ROM) or a random access memory (RAM), and an input-output interface device. The arithmetic processing device of the controller 100 performs arithmetic processing in accordance with a computer program stored in the storage device and outputs control signals for controlling the processing apparatus 1 to the various components of the processing apparatus 1 via the input/output interface device.

The controller 100 is connected to a display unit including a liquid crystal display device that displays the state of the processing operations, images, and the like, for example, an input unit used by an operator for registering processing conditions and the like, and a notifying unit. The input unit includes at least one of a touch panel provided to the display unit or an external input device such as a keyboard. The notifying unit is used to give notice to the operator by emitting at least one of sound or light.

Next, a processing method according to the first embodiment of the present invention will be described in reference to the drawings. FIG. 5 is a flowchart illustrating a flow of the processing method according to the first embodiment. The processing method according to the first embodiment is a method of dividing the device wafer 200 that has the configuration described above, along the plurality of streets 203 that demarcate the devices 204. Moreover, the processing method according to the first embodiment is a method of processing the device wafer 200 by the processing apparatus 1 that has the configuration described above. Specifically, the processing operations performed by the processing apparatus 1 configure the processing method according to the first embodiment. As illustrated in FIG. 5, the processing method according to the first embodiment includes a tape affixing step 1001, a holding step 1002, a cutting step 1003, and a laser processing step 1004.

### (Tape Affixing Step)

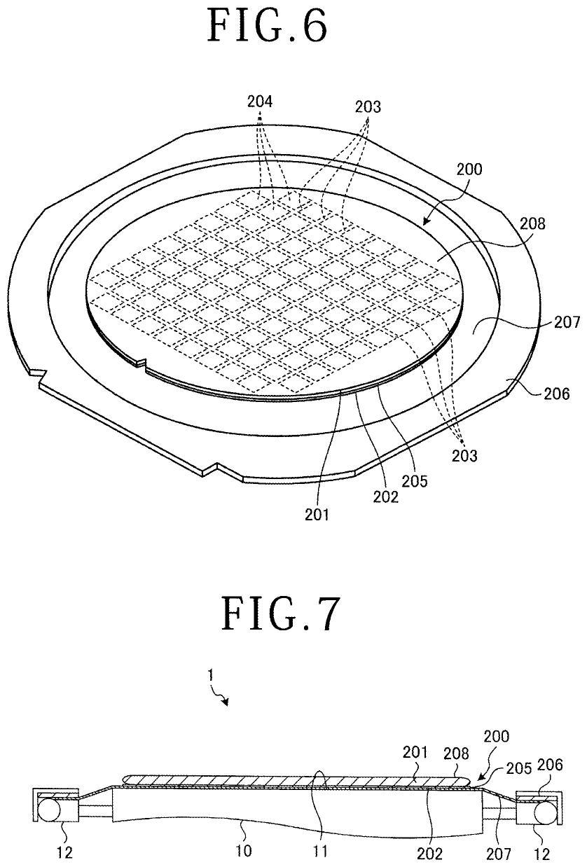

FIG. 6 is a perspective view schematically illustrating the device wafer that has undergone a tape affixing step of the processing method illustrated in FIG. 5. The tape affixing step 1001 is a step of affixing the tape 207 to the face side 202 of the device wafer 200 on which the devices 204 are formed. In the tap affixing step 1001 of the first embodiment, as illustrated in FIG. 6, the tape 207 that has a circular plate shape and is larger in diameter than the device wafer 200 is affixed to the face side 202 of the device wafer 200, the annular frame 206 is mounted to the outer peripheral edge of the tape 207, and the device wafer 200 is supported by the annular frame 206.

### (Holding Step)

FIG. 7 is a schematic cross-sectional side view illustrating the holding step of the processing method illustrated in FIG. 5. The holding step 1002 is a step of holding the face side 202 of the device wafer 200 by the holding table 10 of the processing apparatus 1. In the holding step 1002, first, an operator registers the processing conditions in the controller 100, and the face side 202 of the device wafer 200 to which the tape 207 has been affixed in the tape affixing step 1001 is placed on the holding surface 11 of the holding table 10 in the processing apparatus 1.

In the holding step 1002, the processing apparatus 1 starts the processing operations, that is, the holding step 1002 and subsequent steps of the processing method according to the first embodiment, upon receiving a processing start instruction from the operator. In the holding step 1002, as illustrated in FIG. 7, the processing apparatus 1 holds under suction the face side 202 of the device wafer 200 by the holding surface 11 of the holding table 10 via the tape 207, clamps the annular frame 206 by the clamps 12, rotates the spindle 23 about its axis, and supplies cutting liquid from the cutting liquid nozzle 24 to the cutting blade 21.

### (Cutting Step)

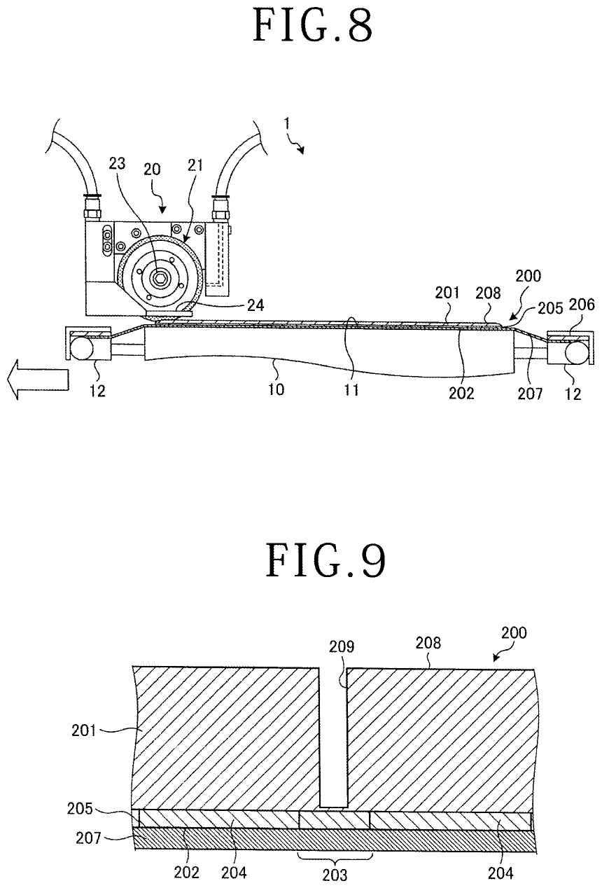

FIG. 8 is a schematic cross-sectional side view illustrating a cutting step of the processing method illustrated in FIG. 5. FIG. 9 is a cross sectional view of the main parts of the device wafer that has undergone the cutting step of the processing method illustrated in FIG. 5. The cutting step 1003 is a step of cutting the device wafer 200 by the cutting blade 21 (illustrated in FIG. 8) from the reverse side 208 of the device wafer 200 along the streets 203 and forming cutting grooves 209 (illustrated in FIG. 9) that do not reach the functional layer 205, after the holding step 1002 is carried out.

In the cutting step 1003, the processing apparatus 1 moves the holding table 10 toward the processing area by the X-axis moving unit 51, captures an image of the device wafer 200 by the imaging unit 30, and controls the moving unit 50 to perform alignment, in reference to the image obtained by the imaging unit 30. In the cutting step 1003, as illustrated in FIG. 8, the processing apparatus 1 moves the holding table 10 along the X-axis direction, for example, and causes the cutting blade 21 to cut into the streets 203 while moving the device wafer 200 and the cutting unit 20 relative to each other along the streets 203.

Note that, in the cutting step 1003 of the first embodiment, the processing apparatus 1 causes the cutting edge of the cutting blade 21 to cut into the streets 203 from the reverse side 208 to a depth where a slight distance is reserved between a lower end of the cutting edge and the functional layer 205. In the cutting step 1003, the processing apparatus 1 performs cutting processing on all the streets 203 of the device wafer 200 held on the holding table 10 and forms the cutting grooves 209 illustrated in FIG. 9 in the streets 203.

### (Laser Processing Step)

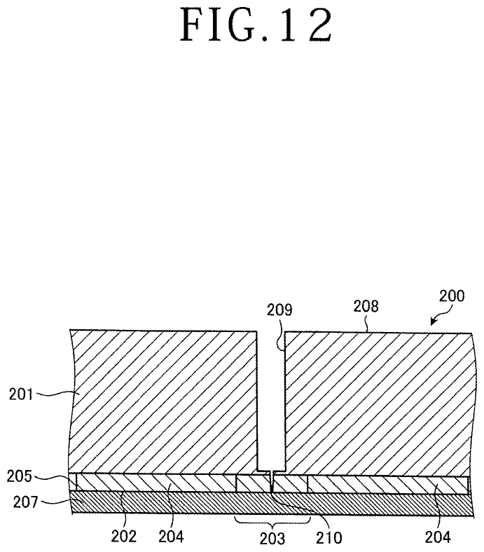

FIG. 10 is a schematic cross-sectional side view illustrating a laser processing step of the processing method illustrated in FIG. 5. FIG. 11 is a cross sectional view schematically illustrating main parts of the beam condenser and the liquid ejector illustrated in FIG. 1. FIG. 12 is a cross sectional view of the main parts of the device wafer that has undergone the laser processing step of the processing method illustrated in FIG. 5.

The laser processing step 1004 is a step of applying the laser beam 41 having a wavelength absorbable by the device wafer 200 to the device wafer 200 from the reverse side 208 of the device wafer 200 along the cutting grooves 209 and cutting the device wafer 200 into individual devices 204, after the cutting step 1003 is carried out. In the first embodiment, the laser processing step 1004 is carried out in a state in which the device wafer 200 is continuously held on the holding table 10 without being unloaded from the holding table 10, after the cutting step 1003 is carried out.

In the laser processing step 1004, the processing apparatus 1 controls the moving unit 50 to perform alignment for aligning the laser beam application unit 42 and the cutting grooves 209. In the laser processing step 1004, the liquid 44 is supplied to the space 463 inside the liquid ejector 46 from the liquid supply pump 47, and, as illustrated in FIGS. 10 and 11, the liquid layer 45 is formed between the lower surface 462 of the liquid ejector 46 and the reverse side 208 of the device wafer 200 held on the holding table 10.

In the laser processing step 1004, the processing apparatus 1 moves the holding table 10 along the X-axis direction, for example, and applies the laser beam 41 to the bottom of the cutting grooves 209 formed in the streets 203, through the liquid layer 45 from the laser beam application unit 42, while moving the device wafer 200 and the laser beam application unit 42 relative to each other along the street 203, as illustrated in FIGS. 10 and 11.

Note that, in the laser processing step 1004 of the first embodiment, the processing apparatus 1 sets the focal point of the laser beam 41 to the bottom of the cutting groove 209, and applies the laser beam 41 to the bottom of the cutting groove 209 formed in each street 203. In the laser processing step 1004, the processing apparatus 1 performs ablation processing on part of the substrate 201 on the bottom of the cutting groove 209 formed in each street 203 and the functional layer 205 to remove part of them, and forms laser processing grooves 210 that penetrate the functional layer 205, on the bottom of the cutting groove 209 formed in each street 203, to thereby divide the device wafer 200 into individual devices 204, as illustrated in FIG. 12. In the manner described above, in the laser processing step 1004, the laser processing unit 40 forms the liquid layer on the reverse side 208 of the device wafer 200 and applies the laser beam 41 to the device wafer 200 through the liquid layer 45.

As described above, the processing method and the processing apparatus 1 according to the first embodiment perform the cutting step 1003 and the laser processing step 1004 in a state in which the face side 202 of the device wafer 200 is held on the holding table 10, so that the risk of adherence of foreign matter produced by cutting processing or ablation processing to the face side 202 of the device wafer 200 can be reduced. Moreover, the processing method and the processing apparatus 1 according to the first embodiment perform the laser processing step 1004 in a state in which the device wafer 200 is continuously held on the holding table 10 without being unloaded from the holding table 10, after the cutting step 1003 is carried out, so that the risk of breakage of the device wafer 200 can also be reduced.

Consequently, the processing method and the processing apparatus 1 according to the first embodiment produce the effect of reducing adherence of foreign matter to the face side 202 of the device wafer 200 and also reducing the risk of breakage of the device wafer 200.

Furthermore, the processing method and the processing apparatus 1 according to the first embodiment apply the laser beam 41 to the device wafer 200 through the liquid layer 45 in the laser processing step 1004. This allows foreign matter such as debris produced in ablation processing to be washed away by the liquid 44, preventing foreign matter such as debris from adhering to the device wafer 200 without any protective film being formed on the reverse side 208.

### Second Embodiment

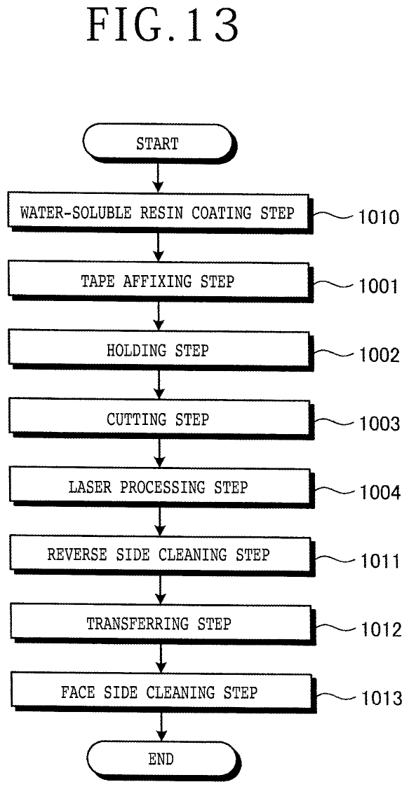

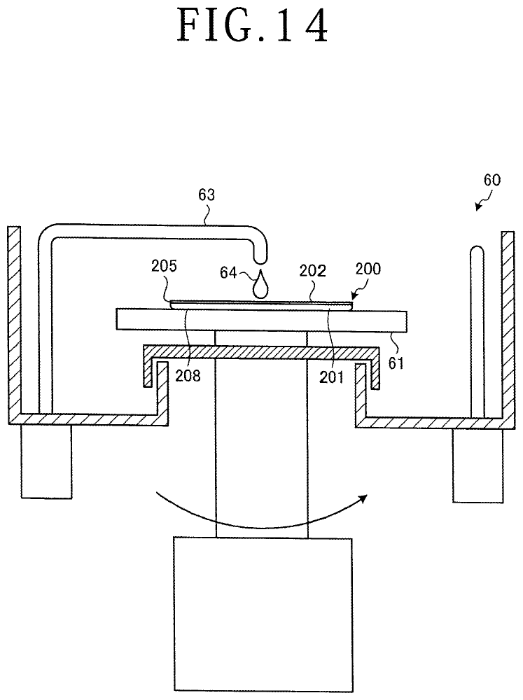

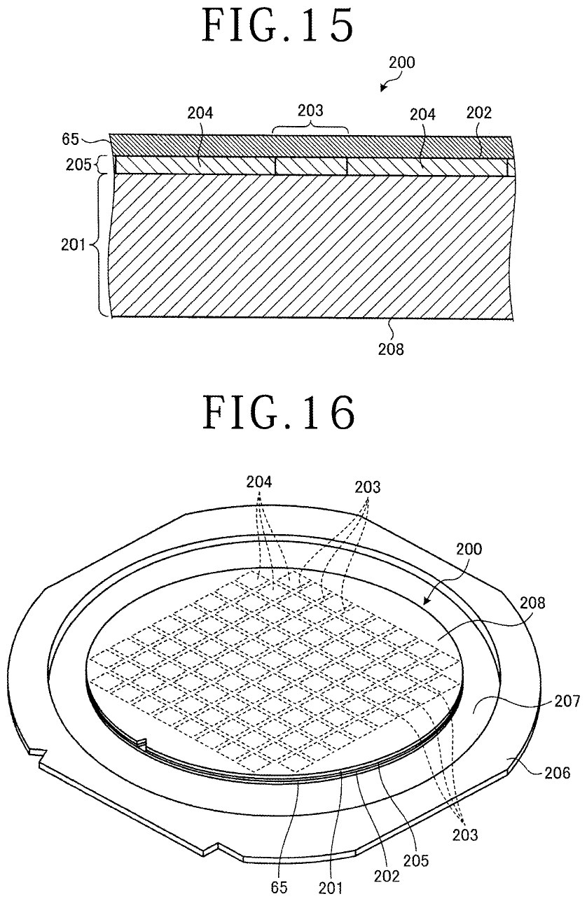

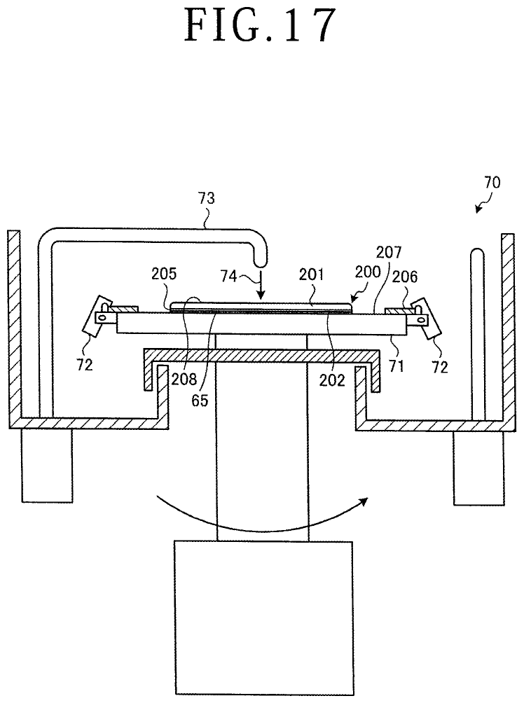

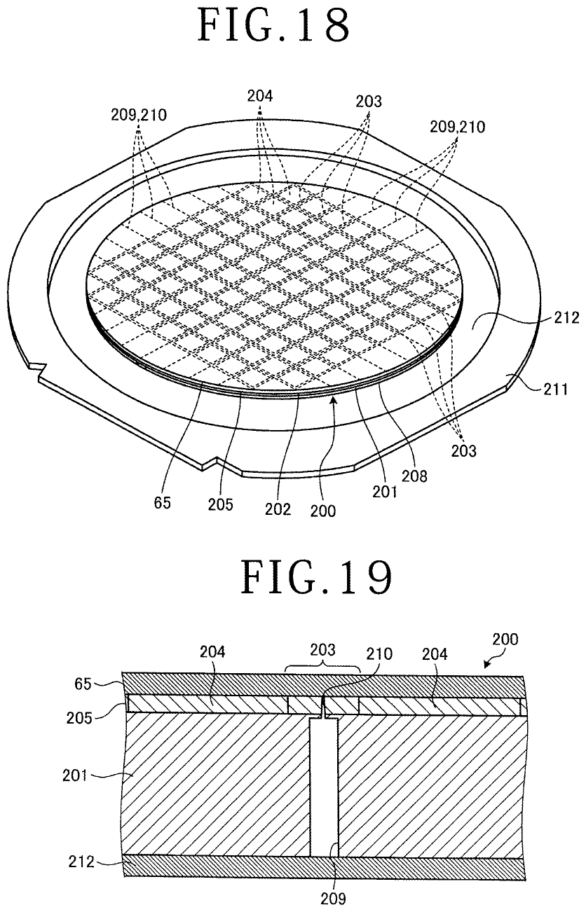

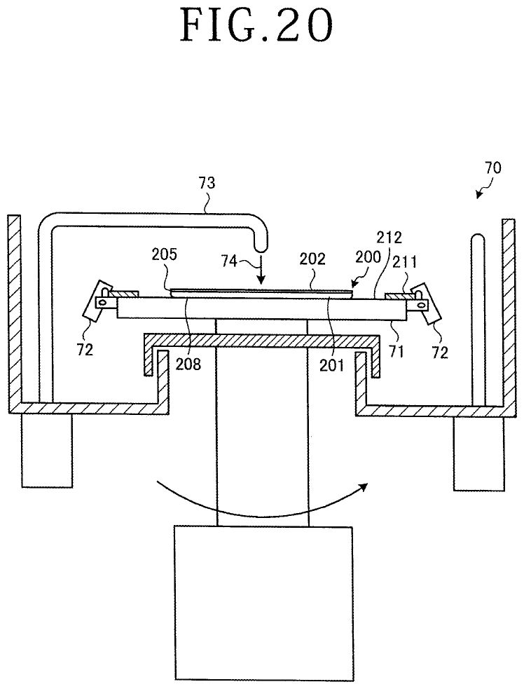

The processing method according to a second embodiment of the present invention will be described in reference to the drawings. FIG. 13 is a flowchart illustrating a flow of the processing method according to the second embodiment. FIG. 14 is a schematic cross-sectional side view illustrating a water-soluble resin coating step of the processing method illustrated in FIG. 13. FIG. 15 is a cross sectional view of the main parts of the device wafer that has undergone the water-soluble resin coating step of the processing method illustrated in FIG. 13. FIG. 16 is a perspective view schematically illustrating the device wafer that has undergone the tape affixing step of the processing method illustrated in FIG. 13. FIG. 17 is a schematic cross-sectional side view illustrating a reverse side cleaning step of the processing method illustrated in FIG. 13. FIG. 18 is a perspective view schematically illustrating the device wafer that has undergone a transferring step of the processing method illustrated in FIG. 13. FIG. 19 is a cross sectional view of the main parts of the device wafer that has undergone the transferring step of the processing method illustrated in FIG. 13. FIG. 20 is a schematic cross-sectional side view illustrating a face side cleaning step of the processing method illustrated in FIG. 13. Note that, in FIGS. 13, 14, 15, 16, 17, 18, 19, and 20, parts identical to those in the first embodiment are denoted by the same reference signs, and their descriptions will be omitted.

The processing method according to the second embodiment includes a water-soluble resin coating step 1010, a reverse side cleaning step 1011, a transferring step 1012, and a face side cleaning step 1013, in addition to the tape affixing step 1001, the holding step 1002, the cutting step 1003, and the laser processing step 1004, as illustrated in FIG. 13. As in the first embodiment, in the processing method according to the second embodiment, the holding step 1002, the cutting step 1003, and the laser processing step 1004 are performed by the processing apparatus 1.

The water-soluble resin coating step 1010 is a step of coating the face side 202 of the device wafer 200 with water-soluble resin 64 before the holding step 1002 is carried out. In the water-soluble resin coating step 1010, a resin coating apparatus 60 holds under suction the reverse side 208 of the device wafer 200 on a holding surface of a spinner table 61, as illustrated in FIG. 14. In the water-soluble resin coating step 1010, the resin coating apparatus 60 rotates the spinner table 61 about its axis and drops the water-soluble resin 64 in liquid form from a water-soluble resin supply nozzle 63 to the center of the face side 202 of the device wafer 200, as illustrated in FIG. 14.

The dropped water-soluble resin 64 flows toward the outer circumferential side from the central side on the face side 202 of the device wafer 200 by the centrifugal force generated by rotation of the spinner table 61, and is applied over the entire face side 202 of the device wafer 200. Note that the water-soluble resin 64 includes, for example, such water-soluble resin as polyvinyl alcohol (PVA) or polyvinylpyrrolidone (PVP). In the water-soluble resin coating step 1010, the water-soluble resin 64 applied over the entire face side 202 of the device wafer 200 is dried, so that, as illustrated in FIG. 15, the entire face side 202 of the device wafer 200 is covered with a protective film 65 including the water-soluble resin 64.

The tape affixing step 1001 of the processing method according to the second embodiment is a step of affixing the tape 207 to the face side 202 of the device wafer 200 after the water-soluble resin coating step 1010 is carried out. In the tape affixing step 1001 of the processing method according to the second embodiment, as illustrated in FIG. 16, the tape 207 that has a circular plate shape and is larger in diameter than the device wafer 200 is affixed to the protective film 65 covering the entire face side 202 of the device wafer 200, the annular frame 206 is mounted to the outer peripheral edge of the tape 207, and the device wafer 200 is supported by the annular frame 206.

In the holding step 1002 of the processing method according to the second embodiment, the processing apparatus 1 holds the face side 202 of the device wafer 200 via the tape 207 and performs the cutting step 1003 and the laser processing step 1004 in this order as in the first embodiment.

The reverse side cleaning step 1011 is a step of cleaning the reverse side 208 of the device wafer 200 after the laser processing step 1004 is carried out. In the reverse side cleaning step 1011, a cleaning apparatus holds under suction the face side 202 of the device wafer 200 on a holding surface of a spinner table 71 via the tape 207 and clamps the annular frame 206 by clamps 72 provided around the spinner table 71, as illustrated in FIG. 17.

In the reverse side cleaning step 1011, the cleaning apparatus 70 supplies cleaning liquid 74 including purified water from a cleaning liquid supply nozzle 73 to the center of the reverse side 208 of the device wafer 200 in a state in which the spinner table 71 is rotated about its axis, as illustrated in FIG. 17. The cleaning liquid 74 supplied to the reverse side 208 of the device wafer 200 flows toward the outer circumferential side from the central side on the reverse side 208 of the device wafer 200 by the centrifugal force generated by rotation of the spinner table 71, to clean the reverse side 208 of the device wafer 200 and remove foreign matter such as debris from the reverse side 208 of the device wafer 200.

The transferring step 1012 is a step of affixing a reverse side tape 212 to the reverse side 208 and removing the tape 207 from the face side 202 of the device wafer 200, after the reverse side cleaning step 1011 is carried out. In the transferring step 1012, as illustrated in FIGS. 18 and 19, the reverse side tape 212 that has a circular plate shape and is larger in diameter than the device wafer 200 is affixed to the reverse side 208 of the device wafer 200, an annular frame 211 is mounted to an outer peripheral edge of the reverse side tape 212, the tape 207 is peeled off from the face side 202, and the device wafer 200 is supported by the annular frame 211.

Note that, in the second embodiment, similarly to the tape 207, the reverse side tape 212 is what is generally called an adhesive tape including a glue layer including adhesive resin and a base material that includes non-adhesive resin and on which the glue layer is laminated. Yet, in the present invention, the reverse side tape 212 may be what is generally called a non-adhesive tape including only a base material including non-adhesive thermoplastic resin such as polyolefin or polyethylene. In a case where the reverse side tape 212 is a non-adhesive tape, the reverse side tape 212 is affixed to the device wafer 200 and the annular frame 211 by thermocompression bonding.

The face side cleaning step 1013 is a step of cleaning the face side 202 of the device wafer 200 and removing the water-soluble resin 64, after the transferring step 1012 is carried out. In the face side cleaning step 1013, the cleaning apparatus 70 holds under suction the reverse side 208 of the device wafer 200 by the holding surface of the spinner table 71 via the reverse side tape 212 and clamps the annular frame 211 by the clamps 72 provided around the spinner table 71.

In the face side cleaning step 1013, the cleaning apparatus 70 supplies the cleaning liquid 74 including purified water from the cleaning liquid supply nozzle 73 toward the center of the face side 202 of the device wafer 200 in a state in which the spinner table 71 is rotated about its axis, as illustrated in FIG. 20. The cleaning liquid 74 supplied to the face side 202 of the device wafer 200 flows toward the outer circumferential side from the central side on the face side 202 of the device wafer 200 by the centrifugal force generated by rotation of the spinner table 71, to clean the face side 202 of the device wafer 200 and remove the protective film 65 including the water-soluble resin 64 from the face side 202 of the device wafer 200, together with foreign matter such as debris.

The processing method and the processing apparatus 1 according to the second embodiment perform the cutting step 1003 and the laser processing step 1004 in a state in which the face side 202 of the device wafer 200 is held on the holding table 10, so that the risk of adherence of foreign matter produced in cutting processing or ablation processing to the face side 202 of the device wafer 200 can be reduced. Further, the processing method and the processing apparatus 1 according to the second embodiment perform the laser processing step 1004 in a state in which the device wafer 200 is continuously held by the holding table 10 without being unloaded from the holding table 10, after the cutting step 1003 is carried out, so that the risk of breakage of the device wafer 200 can be reduced.

Consequently, the processing method and the processing apparatus 1 according to the second embodiment can produce the effect of reducing adherence of foreign matter to the face side 202 of the device wafer 200 and also reducing the risk of breakage of the device wafer 200, similarly to those according to the first embodiment.

Further, the processing method and the processing apparatus 1 according to the second embodiment coat the face side 202 of the device wafer 200 with the protective film 65 including the water-soluble resin 64 in the water-soluble resin coating step 1010, before the tape affixing step 1001 is carried out, so that the devices 204 can be prevented from coming into contact with the tape 207. As a result, the processing method and the processing apparatus 1 according to the second embodiment can prevent the residues of the tape 207 from adhering to the devices 204.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A device wafer processing method of dividing a device wafer having a plurality of devices formed on a face side thereof by a functional layer laminated on a substrate, along a plurality of intersecting streets that demarcate the devices, the processing method comprising:
a holding step of holding the face side of the device wafer by a holding table;
a cutting step of cutting the device wafer by a cutting blade from a reverse side of the device wafer along the streets and forming cutting grooves that do not reach the functional layer, after the holding step is carried out; and
a laser processing step of applying a laser beam having a wavelength absorbable by the device wafer to the device wafer from the reverse side of the device wafer along the cutting grooves and dividing the device wafer into individual devices, after the cutting step is carried out, wherein
the laser processing step is carried out in a state in which the device wafer is continuously held on the holding table without being unloaded from the holding table, after the cutting step is carried out.

2. The device wafer processing method according to claim 1, wherein, in the laser processing step, a liquid layer is formed on the reverse side of the device wafer, and the laser beam is applied to the device wafer through the liquid layer.

3. The device wafer processing method according to claim 1, further comprising:
a water-soluble resin coating step of coating the face side of the device wafer with water-soluble resin before the holding step is carried out; and
a tape affixing step of affixing a tape to the face side of the device wafer after the water-soluble resin coating step is carried out, wherein,
in the holding step, the face side of the device wafer is held via the tape.

4. The device wafer processing method according to claim 3, further comprising:
a reverse side cleaning step of cleaning the reverse side of the device wafer after the laser processing step is carried out;
a transferring step of affixing a reverse side tape to the reverse side of the device wafer and removing the tape from the face side of the device wafer, after the reverse side cleaning step is carried out; and
a face side cleaning step of cleaning the face side of the device wafer and removing the water-soluble resin, after the transferring step is carried out.

5. A processing apparatus that divides a device wafer having a plurality of devices formed on a face side thereof by a functional layer laminated on a substrate, along a plurality of intersecting streets that demarcate the devices, the processing apparatus comprising:
a holding table that holds the face side of the device wafer;
a cutting unit that has a spindle to which a cutting blade that cuts the device wafer held on the holding table is mounted; and
a laser processing unit that includes a laser oscillator that emits a laser beam having a wavelength absorbable by the device wafer and a beam condenser that focuses the laser beam emitted from the laser oscillator, to the device wafer held on the holding table.

6. The processing apparatus according to claim 5, wherein
the cutting unit includes a cutting liquid nozzle that supplies cutting liquid to the cutting blade, and
the laser processing unit further includes a liquid layer forming unit that supplies liquid to the reverse side of the device wafer held on the holding table and forms a liquid layer, and the laser processing unit applies the laser beam to the device wafer through the liquid layer.
